(19) United States
(12) Patent Application Publication
(10) Pub. No.: US 2025/0391828 A1
(43) Pub. Date: Dec. 25, 2025

(54) Method for Producing a Semiconductor Component Assembly

(71) Applicant: IMEC VZW, Leuven (BE)

(72) Inventors: Robert Miller, Lubbeek (BE); Hamideh Jafarpoorchekab, Heverlee (BE); Nelson Pinho, Leuven (BE); Xiao Sun, Wilsele (BE); Siddhartha Sinha, Kessel-Lo (BE)

(21) Appl. No.: 19/243,952

(22) Filed: Jun. 20, 2025

(30) Foreign Application Priority Data
Jun. 20, 2024 (EP) 24183356.5

(51) Int. Cl. H01L 25/00; H01L 21/56; H01L 21/768; H01L 23/00

(52) U.S. Cl. CPC H01L 25/50; H01L 21/56; H01L 21/76898; H01L 23/562; H01L 24/80; H01L 2224/80895

(57) ABSTRACT

The method of the present disclosure is related to the assembly of two components on two opposite sides of a substrate, enabled by the embedding of one of the components in a stress-compensated SiO₂ layer applied at low temperatures, i.e. lower than any temperature that could compromise the functionality of the embedded component. Example embodiments are related to heterogeneous integration schemes, i.e. the assembly of components of different types, in particular a CMOS chip and a III-V chip, which are otherwise difficult to integrate in a 3D package. The stress-compensated film embeds the component at least laterally, i.e. the layer surrounds and is in direct contact with the sides of the component and the thickness of the film is at least equal to the thickness of the component.

### CROSS-REFERENCE TO RELATED APPLICATIONS

The present application is a non-provisional patent application claiming priority to European Patent Application No. 24183356.5, filed Jun. 20, 2024, the contents of which are hereby incorporated by reference.

### FIELD OF THE DISCLOSURE

The present disclosure is related to the field of semiconductor processing, in particular to the semiconductor component assembly, also referred to as packaging.

### BACKGROUND

A development that continues to gain prominence in the semiconductor industry is the so-called heterogeneous integration packaging, i.e. the integration of non-silicon-based components like III-V based dies with silicon-based components like CMOS chips into a complete system. One area of interest in this regard is the development of wireless communication solutions which will power future generations of telecom devices.

Current heterogeneous integration schemes include so-called 2.5D schemes, wherein for example a III-V chip and a CMOS chip are bonded side by side on an interposer substrate. This scheme may improve thermal management as both chips can be in contact with the same heat sink. However, it intrinsically involves horizontal interconnect lines which lead to unacceptable losses at high frequencies applicable in RF (radio frequency) applications. Also, in 5G and future 6G applications, 2D beam steering becomes a requirement, which is possible only when applying 3D heterogeneous integration schemes, wherein for example a III-V chip is mounted on top of a CMOS chip. The thermal management of these 3D configurations is however problematic.

### SUMMARY

The present disclosure aims to provide a method for assembling semiconductor components which does not suffer from the above problems. The method of the present disclosure is related to the assembly of two components on two opposite sides of a substrate, enabled by the embedding of one of the components in a stress-compensated SiO₂ layer applied at low temperatures, i.e. lower than any temperature that could compromise the functionality of the embedded component. The example embodiments are related to a heterogeneous integration scheme, i.e. the assembly of components of different types, in particular a CMOS (complementary metal-oxide semiconductor) chip and a III-V chip, which are otherwise difficult to integrate in a 3D package.

The stress-compensated film embeds the component at least laterally, i.e. the layer surrounds and is in direct contact with the sides of the component and the thickness of the film is at least equal to the thickness of the component. In some example embodiments, the method includes depositing the stress-compensated film followed by planarizing the film to a level parallel to and possibly coinciding with the component's upper surface. This may include thinning the component and the film together to a common planarized level.

The fact that the stress-compensated film is applied at temperatures which do not compromise the functionality of the component embedded in the film, together with the fact that the film is stress-compensated enables mounting the component on one side of the substrate and continuing to process the substrate on the opposite side thereof, without unallowable warping of the substrate.

The components on opposite side of the substrate are partly overlapping and are electrically interconnected by through semiconductor vias through the substrate. This assembly thereby represents a 3D packaging solution that enables the use of short low-loss interconnects and enables 2D beam steering when combining a CMOS chip and III-V component in an RF package. For 2D beam steering it is needed to follow the half wavelength pitch in both X and Y directions. The half wavelength pitch scales with frequency and is typically smaller than the combined size of the III-V and CMOS component at mm-wave frequencies. Therefore, placing the III-V and CMOS on opposite sides of the semiconductor package will allow to save space and follow the half wavelength pitch. At the same time, the components are not directly bonded to each other so that thermal management problems related to such direct bonding configurations are avoided.

The present disclosure is in particular related to a method for assembling and interconnecting a first and a second semiconductor component, the components having predefined functionalities, the method comprising the steps of:
providing a semiconductor substrate having a front side and a back side,
producing a plurality of through semiconductor vias at the front side of the substrate, the vias reaching down to a given depth that is smaller than the substrate's thickness,
producing a first redistribution layer on the front side of the semiconductor substrate, the first redistribution layer comprising electrical connections to the vias, and further comprising on its upper surface a plurality of first contact pads,
thinning the substrate from the back side thereof, until the through semiconductor vias are exposed,
producing a second redistribution layer on the back side of the thinned semiconductor substrate, the second redistribution layer comprising electrical connections to the vias, and further comprising on its upper surface a plurality of second contact pads,
wherein the first component is a silicon CMOS chip and the second component is a III-V chip, and wherein the method further comprises:
bonding the first component to one of the first and second redistribution layers directly after producing one of the redistribution layers, by a bonding method configured to realize electrical connections between a number of the first or second contact pads of the respective first or second redistribution layer and corresponding contact pads on the first component,
after bonding the first component to one of the redistribution layers, producing a silicon dioxide film at a temperature that is compatible with the functionality of the first component. A temperature that is compatible with the functionality of the first component is a temperature that is lower than any temperature that could compromise the functionality of the first component. The silicon dioxide film comprises a sequence of mutually stress-compensating layers. This is done by tuning the deposition of the layers so that the layers are alternately subjected to tensile and compressive stresses so that the silicon dioxide film as a whole is essentially stress-compensated. The film embeds the first component at least laterally.
bonding the second component to the other of the first and second redistribution layers directly after producing the other of the redistribution layers, by a bonding method configured to realize electrical connections between a number of the first or second contact pads of the respective first or second redistribution layer and corresponding contact pads on the second component, and wherein the second component is at least partially overlapping the first component.

According to an embodiment, the first component has a given thickness and a planar upper surface, and producing the silicon dioxide film includes:
depositing the sequence of mutually stress-compensating layers to form a layer stack covering the first component and having a thickness at least equal to the thickness of the first component,
planarizing the layer stack so that the upper surface of the planarized layer stack is parallel to the upper surface of the first component, and wherein the planarized layer stack constitutes the silicon dioxide film.

According to an embodiment, the planarizing step includes exposing the upper surface of the first component.

According to an embodiment, the planarizing step includes simultaneously thinning the first component and the layer stack.

According to an embodiment, the method further comprises the step of attaching an antenna chip to the III-V chip, after the III-V chip has been bonded to the first redistribution layer.

According to an embodiment, the method further comprises the step of producing one or more through dielectric vias through the thickness of the silicon dioxide film.

According to an embodiment, the first and/or the second component are bonded respectively to the one and the other of the redistribution layers by hybrid bonding.

According to an embodiment, the first and/or the second component are bonded respectively to the one and the other of the redistribution layers by solder bonding.

### BRIEF DESCRIPTION OF THE FIGURES

The above, as well as additional, features will be better understood through the following illustrative and non-limiting detailed description of example embodiments, with reference to the appended drawings.

FIG. 1 illustrates a production step with a semiconductor substrate, according to an example embodiment.

FIG. 2 illustrates a production step with semiconductor vias in the substrate, according to an example embodiment.

FIG. 3 illustrates a production step with a redistribution layer on the surface of the substrate and vias, according to an example embodiment.

FIG. 4 illustrates a production step with the substrate flipped and attached face-down to a carrier substrate, according to an example embodiment.

FIG. 5 illustrates a production step with the substrate thinned and vias exposed, according to an example embodiment.

FIG. 6 illustrates a production step with a second redistribution layer, according to an example embodiment.

FIG. 7 illustrates a production step with a CMOS chip bonded to the upper surface of the second redistribution layer, according to an example embodiment.

FIG. 8 illustrates a production step with the CMOS chip embedded in a layer stack of silicon dioxide, according to an example embodiment.

FIG. 9 illustrates a production step with the reduction of the thickness of the layer stack, according to an example embodiment.

FIG. 10 illustrates a production step with via connections produced through the SiO₂ film, according to an example embodiment.

FIG. 11 illustrates a production step with the carrier substrate with the thinned substrate flipped and bonded face down to a second carrier substrate, according to an example embodiment.

FIG. 12 illustrates a production step with the first carrier layer and first temporary bonding layer stripped, according to an example embodiment.

FIG. 13 illustrates a production step with bonding pads produced on the contact pads, according to an example embodiment.

FIG. 14 illustrates a production step with the III-V chip bonded to the first redistribution layer, according to an example embodiment.

FIG. 15 illustrates a production step with the attachment of an antenna chip to the back side of the III-V chip, according to an example embodiment.

FIG. 16 illustrates a production step with the antenna chip encapsulated in a dielectric layer, according to an example embodiment.

FIG. 17 illustrates a production step with the second carrier substrate flipped and temporarily bonded to a third carrier substrate, according to an example embodiment.

FIG. 18 illustrates a production step with the second carrier and its temporary bonding layer removed, according to an example embodiment.

FIG. 19 illustrates a production step with under bump metal (UBM) pads applied to the vias, according to an example embodiment.

FIG. 20 illustrates a possible implementation of a package comprising the component assembly, according to an example embodiment.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

One embodiment of the method of the present disclosure will be described in detail, although the present disclosure is not limited to the particular configuration produced by this embodiment. The embodiment concerns a telecommunication package comprising a CMOS chip and a III-V chip coupled to an antenna, wherein the CMOS chip and the III-V chip are interconnected electrically in a manner to enable signal processing of radio frequency signals received through the antenna and to generate signals for transmission by the antenna. The chips as such as well as the antenna may be in accordance with known technology. The characteristic features of the present disclosure are defined by specific method steps applied during the assembly of the package, as described hereafter.

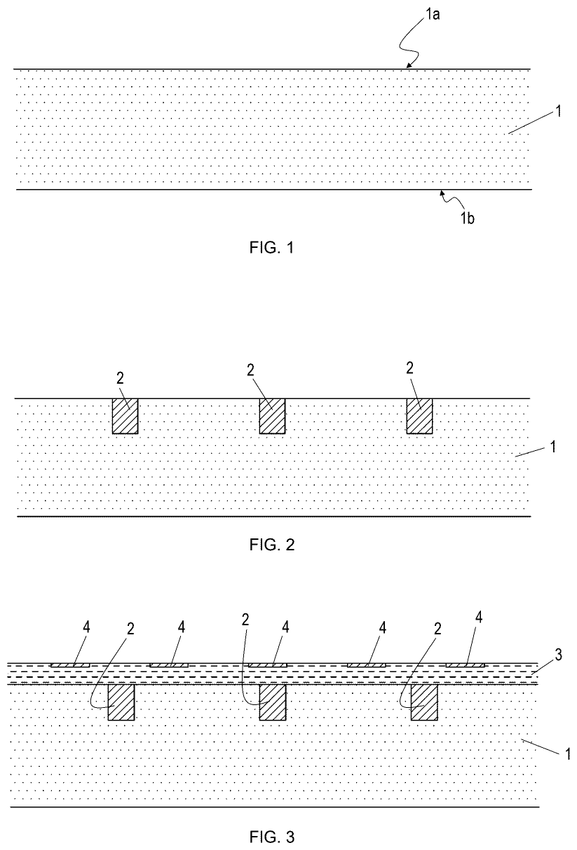

With reference to FIG. 1, a semiconductor substrate 1 is provided having a thickness of about 400 μm. The substrate may be thicker, for example it may be a standard silicon process wafer of 200 mm or 300 mm in diameter and with a thickness respectively of 725 μm or 775 μm.

The image shows a cross section of a small portion of the substrate 1. The substrate has a front side 1a and a back side 1b. As shown in FIG. 2, a plurality of through semiconductor vias 2 are produced in the substrate 1, at the front side thereof. These are pillar-shaped electrical connections which may have a height of about 100 μm for example. The vias 2 can be produced by known methods including lithography and etching for creating pillar-shaped cavities, and electroplating or other deposition techniques, for filling the cavities with an electrically conductive material. In some example embodiments, this electrically conductive material is a metal such as copper. Details of such techniques are well-known and therefore not described here. A planarization technique, equally well-known as such, is applied for planarizing the upper surface of the substrate 1 so that the upper surfaces of the vias 2 are at the same level as the substrate surface, as illustrated in FIG. 2.

With reference to FIG. 3, a redistribution layer 3 is produced on the common planarized surface of the substrate 1 and the vias 2. A redistribution layer is defined within the present context as a multilevel interconnect structure comprising via connections and horizontal interconnect lines embedded in stacked layers of dielectric material. Such a multilevel structure is well known from back end of line processing in the semiconductor industry, and can be produced by known techniques such as damascene-type processing steps. Details of the redistribution layer 3 are not shown in the drawing, except for the presence of contact pads 4 which are coplanar with the upper surface of the redistribution layer 3. The contact pads 4 are electrically connected to one or more of the vias 2 through conductors within the redistribution layer 3, arranged according to a given layout designed to enable the electrical connections.

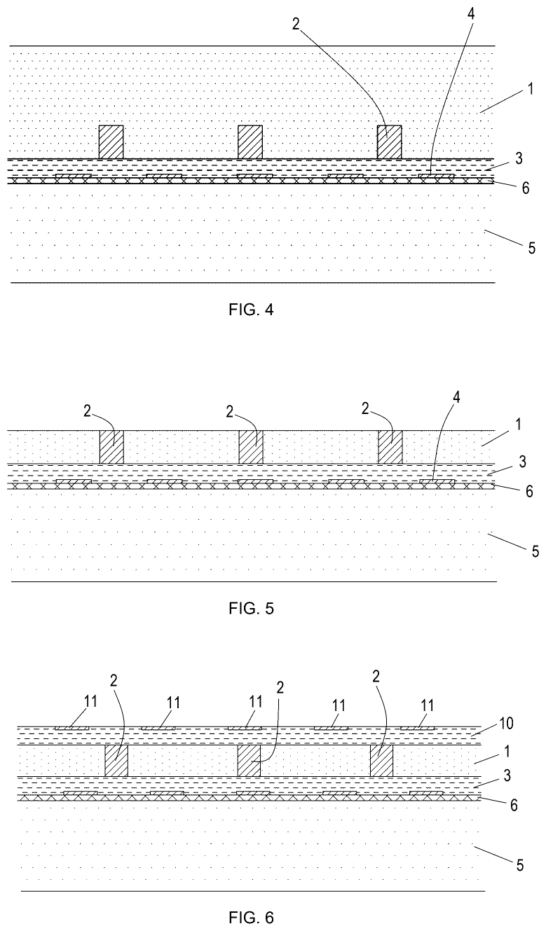

The substrate 1 is then flipped and attached face-down to a carrier substrate 5 through a temporary bonding layer 6, as illustrated in FIG. 4. The temporary bonding layer 6 is formed of a removable adhesion material known as such. The substrate 1 is subsequently thinned from the back side, until the vias 2 are exposed, as illustrated in FIG. 5. This may be done by known grinding and planarization techniques, such as chemical mechanical polishing, possibly thinning the vias 2 to a small degree so that these vias are exposed in the planarized back surface of the thinned substrate 1.

A second redistribution layer 10 is then produced on the thinned backside of the substrate 1, as illustrated in FIG. 6. The second redistribution layer 10 equally includes a number of interconnect levels, and a plurality of contact pads 11 which are coplanar with the upper surface of the second redistribution layer 10.

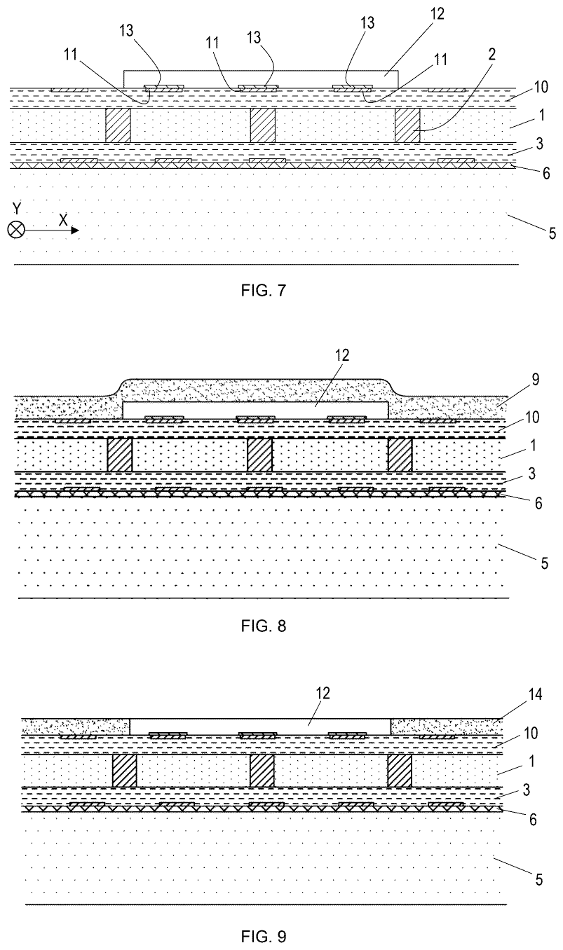

As shown in FIG. 7, a CMOS chip 12 is bonded to the planar upper surface of the second redistribution layer 10, by a suitable bonding technique. In the embodiment shown, the applied technique is known as hybrid bonding but another bonding technique can be used as well, such as for example solder bonding or any other technique known to the person skilled in the art. The chip 12 comprises a number of contact pads 13 embedded in a dielectric material. By the hybrid bonding technique, the bonding surfaces are brought together, both surfaces consisting of dielectric material with the respective contact pads 11 and 13 embedded therein. The bond that is realized is a direct dielectric-to-dielectric bond and metal-to-metal bond between the respective corresponding materials, realized by mutual alignment of the contact pads 11 and 13 and by the application of a suitable bonding temperature and possibly a bonding pressure. Details of the hybrid bonding technique are known as such and therefore not described here in further detail.

The chip 12 represented in the drawings is not necessarily drawn to scale. The lateral dimensions of the chip 12 could be larger than shown in the drawing and the number of contact pads 13 on the CMOS chip 12 and the corresponding number of pads 11 on the substrate 1 could be much higher than the number illustrated in the drawing. The contact pads 11 and 13 could be arranged in a rectangular array extending in the X and Y directions indicated in FIG. 7. The height of the CMOS chip 12 may be in the order of a few tens of micrometers, for example about 50 μm.

With reference to FIG. 8, the CMOS chip 12 is embedded in a layer stack 9 of silicon dioxide (SiO₂) layers. The SiO₂ layer stack 9 is formed by a specific technique, wherein consecutive layers of SiO₂ are formed by chemical vapor deposition steps, applying deposition temperatures which are compatible with the functionality of the CMOS chip 12. In other words, the deposition temperature is lower than any temperature that could compromise the chip's functionality. In example embodiments, the deposition temperature is lower than 400° C. It may be required to lower the deposition temperature towards even lower temperatures based on specific considerations other than the preservation of the chip's functionality. For example, if the temporary bonding layer 6 is an organic bonding layer, the deposition temperature may be below 250° C. in order not to compromise the temporary bonding force.

The deposition of the consecutive SiO₂ layers is furthermore tuned so that the layers are alternately subjected to tensile and compressive stresses, at stress levels configured so that the film as a whole is essentially stress-compensated, i.e. the net stress level in the layer stack 9 is minimal during subsequent processing steps, so that warping of the substrate 1 during the processing steps is minimized.

Methods for producing such a stress-compensated multilayer SiO₂ stack 9 are known as such, and disclosed for example in patent publication document U.S. Pat. No. 9,472,610.

As illustrated in FIG. 8, after the deposition of the stress-compensated layer stack 9, this layer stack 9 covers the surface of the second redistribution layer 10, and the sidewalls and upper surface of the CMOS chip 12. The thickness of the layer stack 9 is higher than the thickness of the CMOS chip 12. The layer stack 9 follows the topology of the CMOS chip 12.

The next step, illustrated in FIG. 9, is a planarization step that reduces the thickness of the layer stack 9 to the thickness of the chip 12, for example at about 50 μm. The chip is now laterally embedded in the stress-compensated SiO₂ film 14 (the film 14 is the planarized and thinned layer stack 9).

According to an alternative embodiment, the layer stack 9 is not thinned to the level of the chip's upper surface, but the layer stack is planarized to a level above the upper surface of the chip 12, so that the upper surface is not exposed. This may be beneficial as it provides more mechanical stability to the eventual package. However, it is also possible to partially thin down the chip together with the layer stack 9. The latter option or the embodiment illustrated in the drawings, wherein the layer stack 9 is thinned down and planarized to the level of the chip's upper surface, is more beneficial in terms of heat removal, as the surface of the chip is not covered by a heat-insulating SiO₂ layer in these cases.

According to example embodiments, a chip 12 is provided having rounded edges, which is beneficial in terms of minimizing local stress concentrations in the SiO₂ film 14 in the vicinity of the edges.

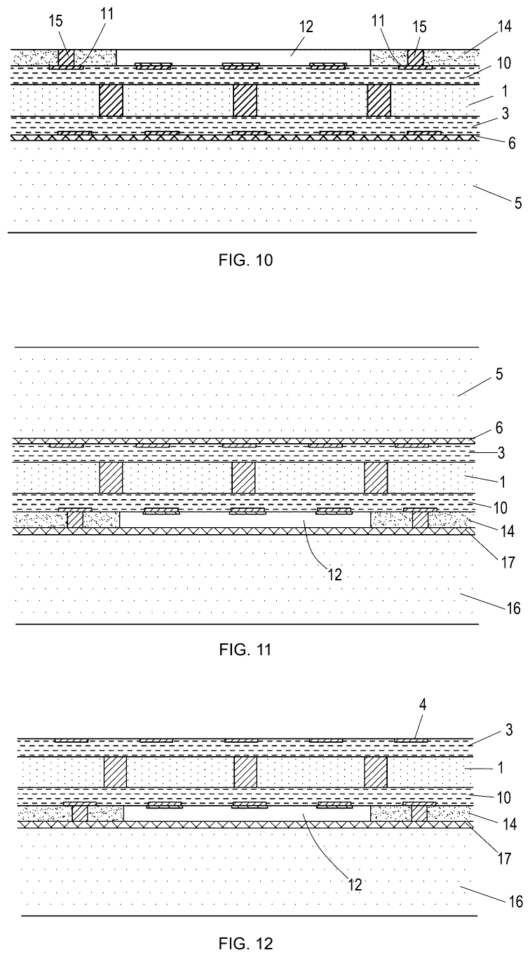

With reference to FIG. 10, via connections 15 may be produced through the SiO₂ film 14, and connected to respective contact pads 11 of the second redistribution layer 10. These via connections 15 can be produced by known lithography, etch and metal fill processes, which may involve the creation of via openings and the filling of these openings with metal such as copper, followed by planarization to bring the upper surface of the vias 15 to the same level as the upper surface of the CMOS chip 12, or to the level of the planarized surface of the SiO₂ film 14 if a given thickness of SiO₂ remains above the chip 12.

The carrier substrate 5 with the thinned substrate 1 attached thereto is then flipped and bonded face down to a second carrier substrate 16, again by a temporary bonding layer 17, as shown in FIG. 11, after which the first carrier 5 and the first temporary bonding layer 6 are stripped, resulting in the image shown in FIG. 12.

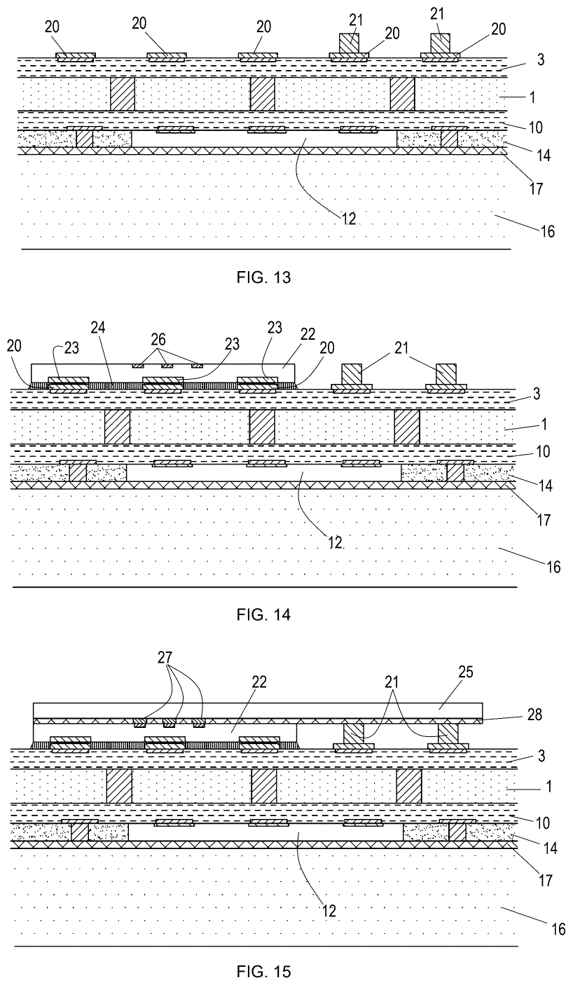

The first redistribution layer 3 and the contact pads 4 embedded therein are now again exposed. With reference to FIG. 13, bonding pads 20 are produced respectively on the contact pads 4. These bonding pads are also known as so-called under bump metal (UBM) pads suitable for receiving thereon a solder material for establishing solder connections. Materials of these pads 20 and methods steps for producing the pads 20 are known as such.

In the illustrated embodiment, some of the UBM pads 20 are provided with conductive pillars 21 of several tens of micrometers in height, formed also according to known methods. Both the UBM pads 20 and the pillars 21 can for example be produced by a known semi-additive fabrication method.

Then, the III-V chip 22 is bonded to the first redistribution layer 3 by solder bonding, as illustrated in FIG. 14. The III-V chip comprises contact pads 23 which are aligned to corresponding UBM pads 20 on the first redistribution layer 3 and the bond is established by solder bumps interposed between the contact pads 23 and the UBM pads 20 and by a suitable solder anneal process inducing the solder to melt and form intermetallic compounds with the UBM and contact pad materials. After the formation of the solder bonds, an underfill material 24 is applied. According to alternative embodiments, the III-V chip 22 may be bonded to the first redistribution layer 3 by hybrid bonding as described above.

With reference to FIG. 15, the next step concerns the attachment of an antenna chip 25 to the back side of the III-V chip 22. The III-V chip 22 comprises back side contacts 26 configured to be connected to corresponding contacts 27 on the antenna chip 25. The antenna chip 25 is attached to the III-V chip 22 by an adhesive layer 28. The lateral dimensions of the antenna chip 25 are such that the antenna chip overlaps both the footprint of the III-V chip 22 on the first redistribution layer 3 and of the CMOS chip 12 on the second redistribution layer 10. In the embodiment shown, the antenna chip 25 is supported by at least two of the Cu pillars 21, as shown in FIG. 15. In this particular case, these two pillars do not establish an electrical connection but they are mainly included to provide mechanical support for the antenna chip 25. It is however also possible to realize a configuration wherein at least some of the pillars 21 are effectively serving as electrical connections.

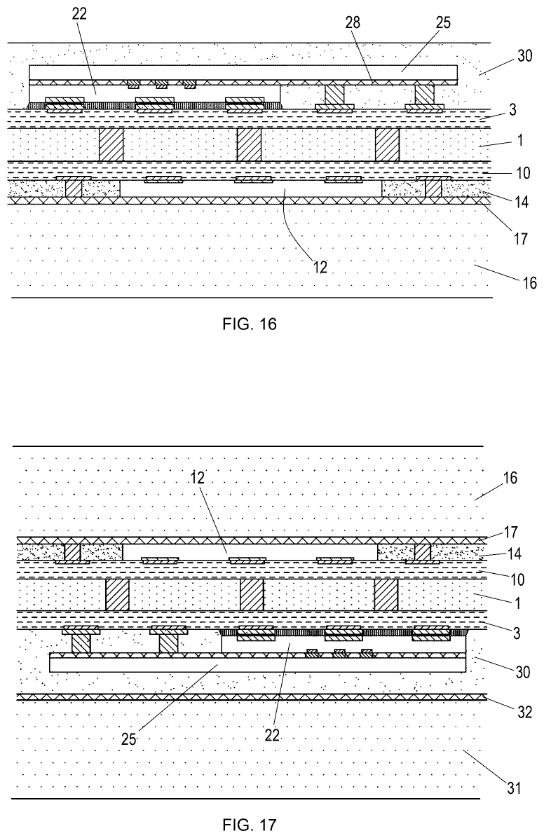

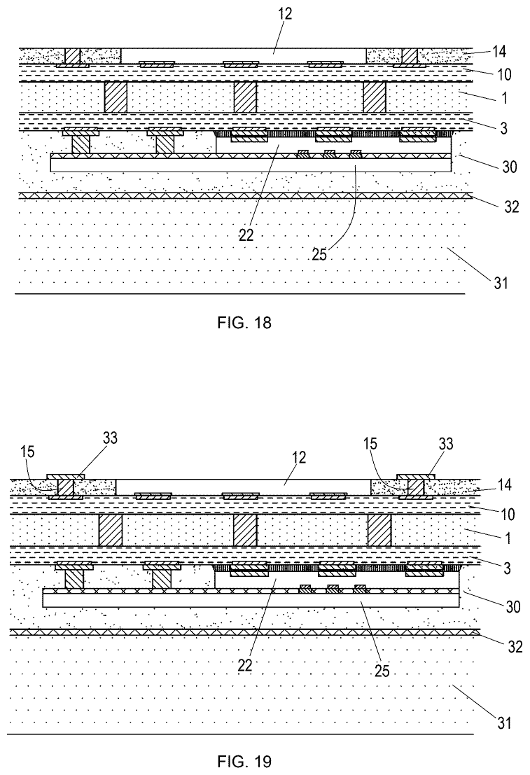

Following this and with reference to FIG. 16, the antenna chip 25 is encapsulated in a dielectric layer 30. This may be a polymer for example, with a dielectric constant lower than 2. The second carrier substrate 16 is then flipped and temporarily bonded to a third carrier substrate 31 by a further temporary bonding layer 32, as shown in FIG. 17, followed by the removal of the second carrier 16 and its temporary bonding layer 17, resulting in the image shown in FIG. 18. The CMOS chip 12 and its embedding SiO₂ layer 14 are now again exposed.

The method steps described so far result in the fabrication of an assembly comprising the IC chip 12 and the III-V chip 22, bonded on opposite sides of an interposer substrate (this is the thinned original substrate 1 provided with redistribution layers 3 and 10 on both sides thereof). The chips 12 and 22 are partly overlapping and are electrically interconnected by through semiconductor vias 2 through the interposer. This assembly thereby represents a 3D packaging solution that enables the use of short low-loss interconnects and 2D beam steering. At the same time, the III-V chip 22 is not bonded directly to the CMOS chip 12, so that thermal management problems related to such direct bonding configurations are avoided.

The method feature that enables the production of this type of assembly is the application of the stress compensated SiO₂ film 14 embedding the CMOS chip 12. The fact that this layer is applied at temperatures which do not compromise the functionality of the CMOS chip 12, together with the fact that the layer 14 is stress-compensated enables mounting the CMOS chip 12 on one side of the substrate 1 and continuing to process the substrate on the opposite side thereof, without unallowable warping of the substrate.

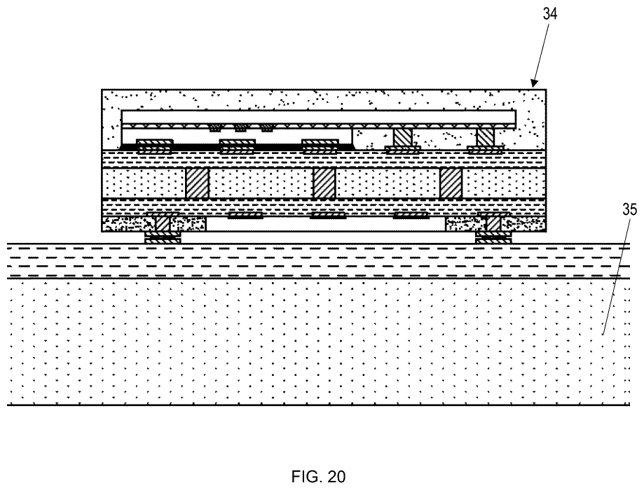

The assembly can be subsequently further processed, for example as illustrated in FIGS. 19 and 20. UBM pads 33 can be applied to the vias 15, as shown in FIG. 19. Alternatively, these pads 33 could be produced earlier in the process sequence, at the stage shown in FIG. 10.

The assembly 34 can then be separated by singulation and bonded, for example by solder bonding, to a larger carrier such as a PCB 35, as illustrated in FIG. 20.

As stated, the present disclosure is not limited to the particular embodiment illustrated in the drawings. In its most general description, the method of the present disclosure is related to the assembly of two components on two opposite sides of an interposer substrate, enabled by the embedding of one of the components in a stress-compensated SiO₂ layer applied at low temperatures, i.e. lower than any temperature that could compromise the functionality of the embedded component. Example embodiments are related to the heterogeneous integration schemes, i.e. the assembly of components of different types, in particular a CMOS chip and a III-V chip, which are otherwise difficult to integrate in a 3D package.

According to an alternative process flow, the CMOS chip 12 is bonded to the first redistribution layer 3 after the production thereof, i.e. at the process stage illustrated in FIG. 3. Thereafter, the chip 12 is embedded in the stress-compensated SiO₂ film 14 in the same manner as described above. The substrate is then flipped and temporarily bonded to a first carrier, i.e. with the planarized surface of the stress-compensated film 14 bonded to the carrier through a temporary adhesion layer. The substrate is then thinned from the back side, and the second redistribution layer 10 is produced on the thinned back side, followed by bonding the III-V chip 22 to the second redistribution layer 10. The antenna chip 25 can be added in the same way as described above. In this approach only one auxiliary carrier substrate may be required. Like the flow shown in the drawings, this alternative process flow is not limited to heterogeneous integration schemes but can be applied to the integration of components of any type, the same or different, mounted on opposite sides of the interposer substrate.

While the present disclosure has been illustrated and described in detail in the drawings and foregoing description, such illustration and description are to be considered illustrative or exemplary and not restrictive. Other variations to the disclosed embodiments can be understood and effected by those skilled in the art, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method for assembling and interconnecting a first and a second semiconductor component, the components having predefined functionalities, the method comprising the steps of:
providing a semiconductor substrate having a front side and a back side,
producing a plurality of through semiconductor vias at the front side of the substrate, the vias reaching down to a given depth that is smaller than the substrate's thickness;
producing a first redistribution layer on the front side of the semiconductor substrate, the first redistribution layer comprising electrical connections to the vias, and further comprising on its upper surface a plurality of first contact pads;
thinning the substrate from the back side thereof, until the through semiconductor vias are exposed; and
producing a second redistribution layer on the back side of the thinned semiconductor substrate, the second redistribution layer comprising electrical connections to the vias, and further comprising on its upper surface a plurality of second contact pads;
wherein the first component is a silicon CMOS chip and the second component is a III-V chip, and wherein the method further comprises:
bonding the first component to one of the first and second redistribution layers directly after producing the one of the redistribution layers, by a bonding method configured to realize electrical connections between a number of the first or second contact pads of the respective first or second redistribution layer and corresponding contact pads on the first component;
after bonding the first component to the one of the redistribution layers, producing a silicon dioxide film at a temperature that is compatible with the functionality of the first component, the silicon dioxide film comprising a sequence of mutually stress-compensating layers, wherein the film embeds the first component at least laterally; and
bonding the second component to the other of the first and second redistribution layers directly after producing the other of the redistribution layers, by a bonding method configured to realize electrical connections between a number of the first or second contact pads of the respective first or second redistribution layer and corresponding contact pads on the second component, and wherein the second component is at least partially overlapping the first component.

2. The method according to claim 1, wherein the first component has a given thickness and a planar upper surface, and wherein producing the silicon dioxide film includes:
depositing the sequence of mutually stress-compensating layers to form a layer stack covering the first component and having a thickness at least equal to the thickness of the first component; and
planarizing the layer stack so that the upper surface of the planarized layer stack is parallel to the upper surface of the first component, and wherein the planarized layer stack constitutes the silicon dioxide film.

3. The method according to claim 2, wherein the planarizing step includes exposing the upper surface of the first component.

4. The method according to claim 3, wherein the planarizing step includes simultaneously thinning the first component and the layer stack.

5. The method according to claim 1, wherein the method further comprises the step of attaching an antenna chip to the III-V chip, after the III-V chip has been bonded to the first redistribution layer.

6. The method according to claim 1, further comprising the step of producing one or more through dielectric vias through the thickness of the silicon dioxide film.

7. The method according to claim 1, wherein the first and/or the second component are bonded respectively to the one and the other of the redistribution layers by hybrid bonding.

8. The method according to claim 1, wherein the first and/or the second component are bonded respectively to the one and the other of the redistribution layers by solder bonding.

9. The method according to claim 1, wherein producing the plurality of through semiconductor vias comprises:
producing pillar shaped cavities by lithography and etching; and
filling the cavities with an electrically conductive material.

10. The method according to claim 9, wherein the electrically conductive material comprises copper.

11. The method according to claim 1, wherein thinning the substrate from the back side thereof further comprises chemical mechanical polishing.

12. The method according to claim 1, wherein the first and second contact pads are arranged in a rectangular array.

13. The method according to claim 1, wherein producing the silicon dioxide film is performed at a temperature less than 400° C.

14. The method according to claim 1, wherein the silicon CMOS chip has rounded edges.

15. The method according to claim 5, wherein attaching the antenna chip to the III-V chip further comprises:
attaching the antenna chip to the III-V chip with an adhesive, wherein the antenna chip is mechanically supported by at least two copper pillars; and
encapsulating the antenna chip in a dielectric layer.

16. The method according to claim 15, wherein the dielectric layer comprises a polymer with a dielectric constant less than 2.

17. The method according to claim 1, wherein the provided semiconductor substrate has a thickness of at least 400 μm.

18. The method according to claim 2, wherein depositing the sequence of mutually stress-compensating layers is performed by chemical vapor deposition.

19. The method according to claim 8, wherein the solder bonding further comprises producing under bump metal (UBM) pads on the contact pads to establish solder connections.

20. The method according to claim 2, wherein the planarizing step further comprises planarizing to a level above the upper surface of the first component, such that the first component is not exposed.
